(19) United States
(12) Patent Application Publication
(10) Pub. No.: US 2008/0121939 A1
(43) Pub. Date: May 29, 2008

(54) Methods of automatically generating dummy fill having reduced storage size

(76) Inventors: Michael Murray, San Jose, CA (US); Van Nguyen, Milpitas, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/593,892

(22) Filed: Nov. 6, 2006

(51) Int. Cl. H01L 27/10; G06F 17/50

(52) U.S. Cl. 257/202; 716/19; 257/E27.081

(57) ABSTRACT

The disclosure relates generally to production of lithography masks such as used in mass production of monolithic integrated circuits (IC's). Layers of such IC's often need to be filled with dummy-fill. In accordance with the disclosure, dummy-objects are first generated by a conventional flat-fill technique and then they are automatically surrounded by outlines that are substantially wrinkle-free. The outlines are cleared of the original flat-fill and then used as areas that are to be automatically tiled by an auto-tiling program. Tiles are then re-filled with array definitions of regularly-spaced dummy-objects. The arrays consume less data storage space than do the original, individually-specified (flat-filled) dummy-objects. The array data is appended to layout data of functional objects in a layer of the integrated monolithic device (IC) to thereby generate a dummy-filled tapeout file. The dummy-filled tapeout file is subjected to pre-tapeout rules checking and then transmitted via a network to a mask house for production of a corresponding lithography mask. The lithography mask is used to mass produce corresponding integrated circuits.

### FIELD OF DISCLOSURE

The present disclosure of invention relates generally to the art of making photolithography masks for use in the fabrication of multilayered and monolithically-integrated devices such as integrated circuit semiconductor devices.

The disclosure relates more specifically to the steps of adding dummy fill features to digitized representations of photolithography masks for the purpose of assuring that the mask patterns are in compliance with fill uniformity specifications, and to the steps of checking the dummy-filled mask definitions and transmitting post-check mask definitions to mask manufacturing facilities.

### DESCRIPTION OF RELATED ART

A modern, monolithically-integrated circuit device (IC) is a technical marvel. It often represents the accumulated expertise of large numbers of technical professionals working in a wide variety of technical arts including that of miniaturization of very complex circuit layouts. Interlaced within this complex hierarchy of expertise are groups of people who carry out steps such as per-die design of functional circuitry, per-layer design of interconnect layout and/or design of layout of other functional features, mask set production and post-production mask inspection, per-layer planarization, photolithography, etching, and post-etch pattern inspection.

Buried among these more well known steps is the arcane art of dummy feature fill. It turns out that various processing operations in semiconductor manufacture are sensitive to average feature density across a layer area. Examples include CPM (chemical mechanical polishing), photolithography and pattern etch. It is sometimes desirable to provide a relatively uniform density of feature fill and of featureless, empty space to density-sensitive process steps. The functional parts of an IC layer layout are rarely of uniform fill density. Thus, featureless empty space between the functional parts are routinely filled with nonfunctional islands or dummy fill features.

Dimensions of, and spacings between dummy fill features and spacings away from functional elements are often application specific. Thus each layer of an integrated circuit (i.e., metal-1, metal-2, etc.) will generally have its own unique set of dummy-fill parameters. A conventional fill method drops individual fill objects in raster scan fashion across a functional layout and then automatically deletes those of the dropped dummy objects that overlap with functional objects or come too close to those functional objects. This provides a relatively good fill of empty spaces and conforms with rules regarding how far away dummy objects should be from functional objects. However, because each dummy fill object is individually defined (typically as a square having two corner coordinates), this raster fill approach consumes large amounts of memory storage space in that it is often used for individually defining thousands or millions of fill objects per layer. The file that contains such multitudes of individually-defined dummy-fill objects (as well as numerous and complex, functional features) can become cumbersome to manage because of its large size.

To overcome this problem, one prior approach tries to automatically tile the whole empty space of a given layer and to then fill the generated tiles with regular arrays of dummy fill objects. An array of regularly-spaced, fill objects can be defined with less data than needed for individually defining the same number of dummy objects once the number exceeds a small threshold value. For example, an array may be defined as an instance of a given, array-starting polygon (i.e., a rectangle having a diagonal with two corner coordinates), row and column repeat numbers and spacing numbers. When the number of polygons defined by the array exceeds a corresponding threshold, the array requires less data storage space than a flat definition wherein the same number of polygons is defined individually, with each individual polygon being specified by its own unique set of critical coordinates. While in the abstract, this tile-and-fill approach sounds like it should work well, there are subtleties to the tile-and-fill approach that tend to leave undesirable empty spaces in the final product. Reasons for why the undesirable empty spaces appear are explored in detail below.

Due to the shortcomings of the tile-and-fill approach, artisans often reluctantly return to the more reliable but storage-consuming, flat-fill technique. It is desirable to have a method whereby the full-fill characteristics of the older flat-fill technique can be had in combination with the data storage efficiencies of the tile-and-fill approach.

### SUMMARY

Structures and methods may be provided in accordance with the present disclosure of invention for improving over the above-summarized shortcomings of the prior flat-fill technique and the prior tile-and-fill approach.

More specifically, in accordance with one aspect of the present disclosure, an automated fill method is provided that comprises: (a) automatically flat-filling a device area with individually specified polygons; (b) automatically and uniformly increasing the dimensions of the individual polygons so that adjacent ones just touch each other and automatically merge to form wrinkle-free outlines of the merged dummy islands; (c) redefining the wrinkle-free outlines as corresponding empty space islands; (d) automatically tiling each of the empty space islands; and (e) filling the tiles with corresponding arrays of polygons. A database is then formed to include array-type descriptions of the tile-filling arrays of polygons.

Without wishing to be bound to any specific theory of operation, it is believed that the merge-and-tile technique works because of the placement and numbers of vertices in the merged dummy islands and the way that general purpose tiling techniques homes in on those vertices as it begins to define tile boundaries.

An integrated device layer in accordance with the disclosure comprises: (a) functional features and (b) dummy-fill features interspersed adjacent to the functional features where the dummy-fill features are defined by corresponding array specifications and the array specifications are products of a process comprised of: (b.1) automatically flat-filling empty parts of the device layer with individually specified polygons; (b.2) automatically generating conformal and substantially wrinkle-free outlines that surround contiguously adjacent ones of the flat-filled, dummy-objects; (b.3) redefining the outlines as corresponding empty space islands; (b.4) automatically tiling each of the empty space islands; and (b.5) generating said array specifications to fill the tiles with corresponding arrays of polygons.

Other aspects of the disclosure will become apparent from the below detailed description.

### BRIEF DESCRIPTION OF THE DRAWINGS

The below detailed description section makes reference to the accompanying drawings, in which:

FIG. 1A includes a schematic top plan view for introducing concepts relating to on-wafer reticle fields, in-die pattern areas, and their relation to fill-sensitive fabrication processes;

FIG. 1B is a side cross sectional view showing the placement of in-die pattern areas in different layers of the wafer of FIG. 1A;

FIG. 1C is a flow chart showing the passing of responsibilities between various technology groups as respective layers of an in-process wafer are specified, as dummy-fill features are added, as corresponding lithography masks are made, as the masks are verified and then used to lithographically expose photosensitive layers, and as the latter layers are developed and patterned to thereby produce integrated devices;

FIG. 2A is a combination flow chart and associated top plan views for explaining a conventional, flat-fill technique of adding dummy-fill features;

FIG. 2B is a combination flow chart and associated top plan views for explaining a conventional, tile-and-fill technique of adding dummy-fill features; and

FIGS. 3A-3B combine to provide a combination flow chart and associated top plan views for explaining a flat-fill, outline, tile and re-fill method in accordance with the invention.

### DETAILED DESCRIPTION

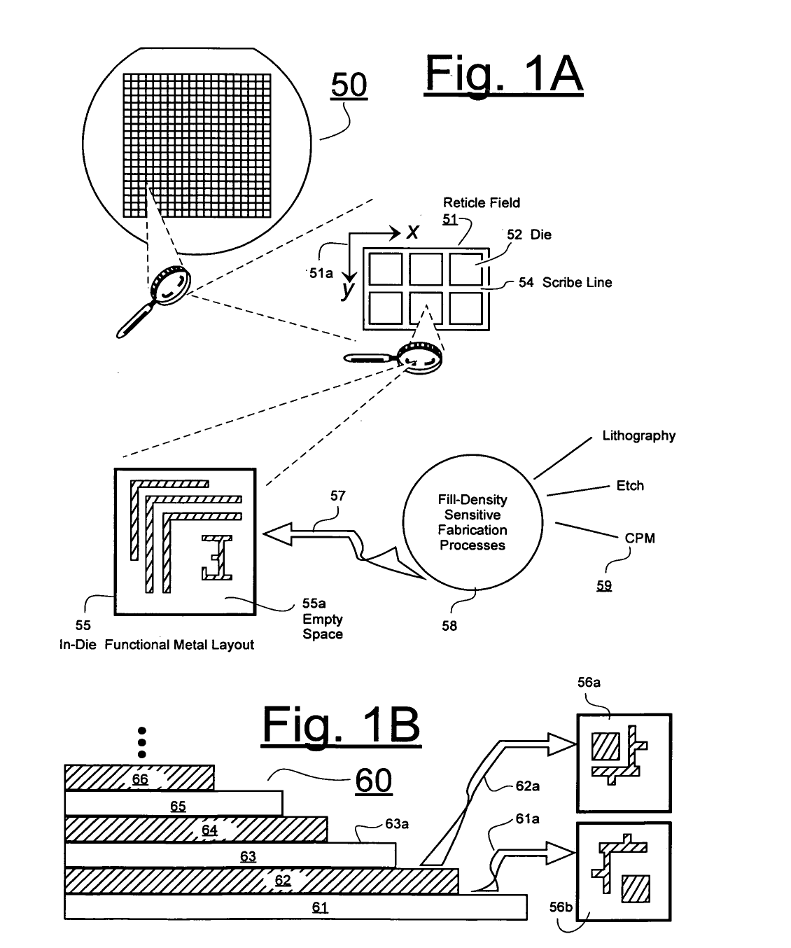

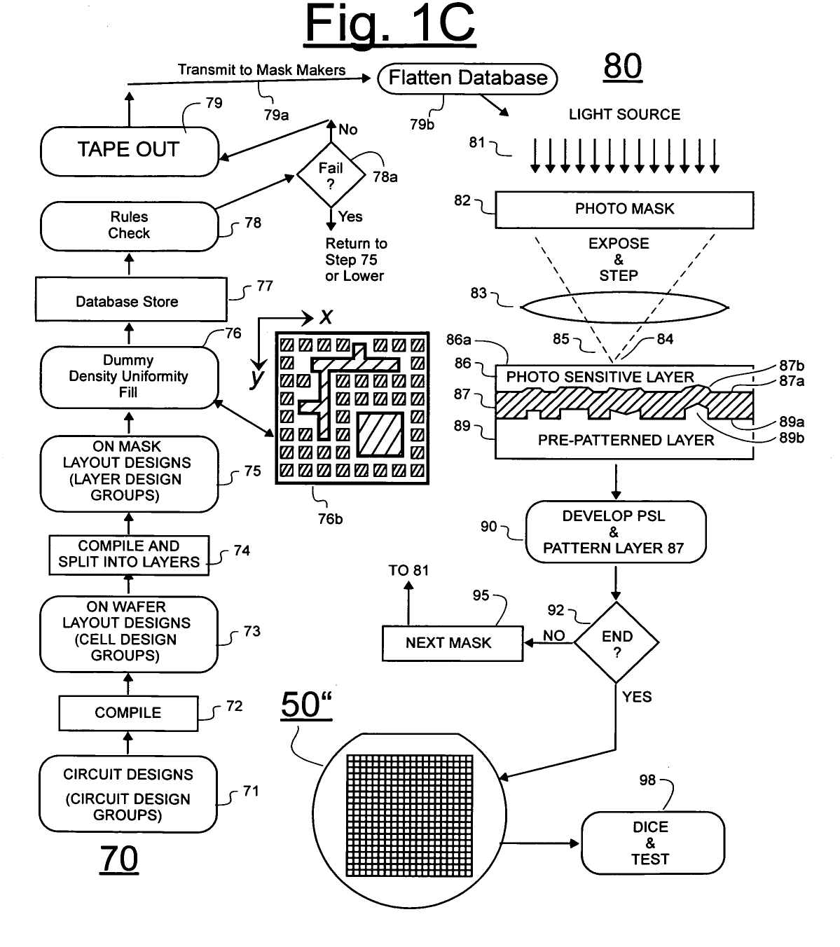

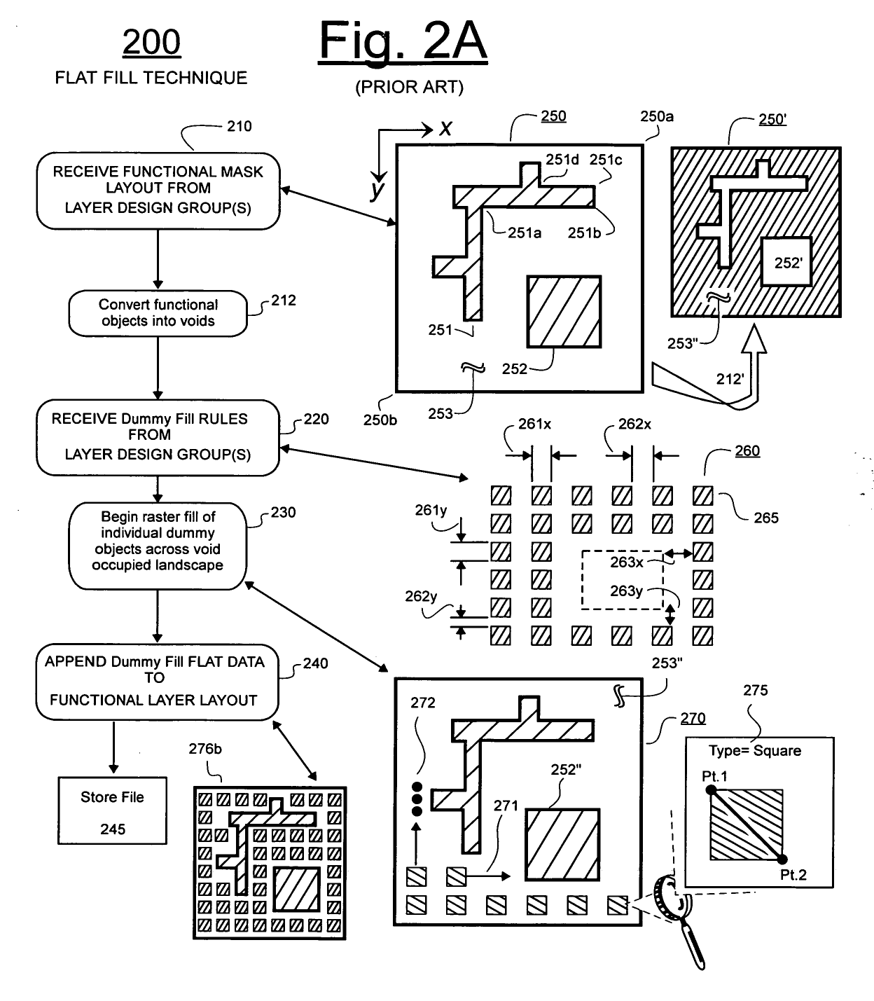

FIG. 1A schematically shows a series of top plan views of a finished integrated circuit wafer 50 and of certain features that may seen on the wafer and/or found within the multiple layers of the finished wafer 50. More specifically, the finished wafer may be seen to have repeated features that are tiled one adjacent to the next so as to give the wafer an appearance of having streets running north-to-south and east-to-west with congested building sections placed between the relatively empty streets. Each of the building-filled sections is conventionally referred to as a die (i.e., 52). Each of the linear and relatively empty streets is conventionally referred to as a “scribe line” (i.e., 54). When the manufacture of the wafer is essentially complete, it is scribed along its scribe lines and broken up into individual dice. The individual dice may be later hermetically sealed into ceramic or plastic packages and sold as individual IC devices. Since the areas of the scribe lines are typically destroyed, such areas are usually devoid of functional (operable) circuitry. Although the dice appear to be crammed with functional features, each layer may contain combinations of non-functional or dummy features and adjacent functional features (i.e., metal interconnect lines).

This first blush recognition of the individual dice and scribe lines can be somewhat misleading. Actually, the wafer 50 is more accurately pictured as being divided into sections known as reticle fields, where each reticle field has two or more dice. An example of a reticle field is shown at 51. The illustrated field 51 contains six (6) dice, with the square denoted as 52 representing one of those dice. The six exemplary dice are arranged as a 3-by-2 rectangular array. Otherwise configured arrays can, of course, be formed. The dice array in field 51 has at least one horizontal scribe line 54 extending through roughly the middle of the reticle field and a number of vertical scribe lines extending through the reticle field in locations that are also spaced away from the edges of the reticle field 51. Associated with each reticle field 51 is a set of patterning masks that define how various layers of the on-wafer reticle field are patterned.

The reticle field 51 may be crudely thought of as an imprint that is left behind by an inked stamp which was sequentially stepped across the wafer so as to stamp out the series of dice and scribe lines shown at 50. That however is still not an accurate picture because the wafer 50 is comprised of a series of different layers stacked one on top of the other. This is better shown in the cross-section of FIG. 1B. The on-wafer reticle field 51 may be better pictured as a stacked series of stamps whose respective patterns have been stepped across the respective stacked layers (e.g., 61-66 of FIG. 1B) of the wafer as the wafer was manufactured. A different “stamp” may be used for each of the different layers of the wafer. For example, in FIG. 1B, the bottommost layer 61 may represent a monocrystalline silicon layer which is sometimes known as the AA layer or the “active area” layer. Another layer 62, positioned further above layer 61, may represent a first polysilicon layer or P1 layer. (Typically, a gate oxide layer is interposed between the active layer 61 and the P1 layer 62.) The P1 layer will typically have a unique pattern of transistor gate regions and polysilicon interconnect lines defined in it. A further layer 63, positioned yet higher on the stack, may represent a first inter-poly dielectric layer (the C1 contact layer). The C1 layer may be used for separating floating and control gates in a stacked flash memory device for instance. Layer 64 may represent a second polysilicon layer (P2) and the yet higher layer 65 may define a second dielectric material (the C2 contact layer) through which a contact mapping is defined to a next, higher conductive layer (e.g., M1). The uppermost of the illustrated layers, 66 may define a first metal layer (M1). There can be many more layers above or between the illustrated ones. It is to be understood that FIG. 1B is merely illustrative and that the layers of a wafer do not have to stepped back from one another as is shown in the figure to expose the on-layer, functional patterns (e.g., 56a, 56b).

Referring again to FIG. 1A, each on-wafer reticle field 51 may be more precisely thought of as being composed of a large plurality of circuit features that are precisely positioned in a coordinate grid 51a of the field 51. A computer database (not yet shown) stores placement coordinates and object shape definitions for each circuit feature provided on each layer of the device. When joined together, the layer definitions form a compiled database structure defining the die 52 and/or reticle field 51. Such a database structure can be massive in size (e.g., many millions of bytes of storage) due to its complexity. It is undesirable to increase the size of that database yet further. However, practitioners are invariably forced to do so because certain fabrication processes are sensitive to average fill densities and fill uniformities. As a result, if a given layer layout; say metal interconnect layout 55 has one or more empty spaces in it such as 55a, practitioners try to fill the empty spaces (55a) with dummy fill features. Database definitions of the dummy fill features can substantially increase the size of the database, making it unwieldy.

When practitioners wish to define a specific geometric shape (a functional or dummy fill feature) that is placed in a specific location within the compiled reticle field 51 (either when the field is located on-wafer or on-mask), they typically specify a code for the shape or type of data object (e.g., square, rectangle, N-sided polygon, array of polygons) and codes for locations of critical points and/or dimensions of critical distances in the specified shape or array. For example, a rectangle object may be defined as being located on-wafer or on-mask and having a diagonal with end points (x=x₁, y=y₁) and (x=x₂, y=y₂) where these x, y coordinates are provided relative to a prespecified grid and its origin. Thus, if a million individual squares are to be defined in flat-fill format (where each square is individually defined), the database will contain four million coordinate values; in other words 4 for each additional object that is so defined in flat-fill format.

For purpose of illustration, FIG. 1A indicates that metal layout 55 can be the product (57) of a number of fabrication process 58 that are each sensitive to in-die or cross-wafer fill densities. Examples of such process are indicated at 59 and may include one or more of a photolithography process that is sensitive to optical proximity effects (OPC), a pattern etch process that is sensitive to edge proximity effects, and a surface smoothing process (e.g., chemical mechanical polishing) that is sensitive to feature density and feature uniformity. In order to provide consistent results, practitioners try to fill the empty spaces (i.e., 55a) with dummy fill patterns of application specific fill densities and fill uniformities.

FIG. 1C is a flowchart that schematically shows more clearly how a dummy fill step (76) may integrate into the process of designing and mass producing a monolithic integrated device 50″. The overall process shown in FIG. 1C is divided into a design section 70 (left side) and a fabrication section 80 (right side). In the design phase 70, a large plurality of circuit designs 71 are formed by respective circuit-design specialty groups. In step 72 the circuit designs of the different groups are compiled to form a more cohesive whole design. For example, the design process may rely on a hierarchy of design cells. Big cells are made of interconnected smaller cells and small cells are made of yet tinier ones. With each compilation of child cells to form an encompassing, parent cell, the complexity of the design grows. At some point, high up on the design-phase's hierarchy tree, the on-wafer 3-D layout designs are formed for the upper-level super cells by respective super-cell design groups. The on-wafer layout designs 73 are then compiled in step 74 to define the full 3-D (three dimensional) structure of the wafer that is to be fabricated. Then that 3-D description is split into respective 2-D layers. The stacked 2-D layers of the original 3-D description are in essence, unstacked and operatively separated from one another. More specifically, one of the on-wafer 2D layout designs may be for the active area layer (AA), a second of the on-wafer 2D layout designs may be for a first contact layer (C1), and so on. These 2D layout designs are typically handled separately after they are logically unstacked from one another.

Each physical 2D layer of the to-be-fabricated wafer can have its own unique composition and its own unique set of requirements for lithography, for patterning and for dummy fill of empty spaces. Accordingly, a different kind of photolithographic mask (or plurality of such masks) may be called for in the fabrication of each unique 2D layer (e.g., AA, P1, C1, P2, C2, etc.). In step 75 the respective on-mask layout designs for each respective photolithographic mask are prepared by the corresponding layer design groups. Part of the per-layer design effort is shown in step 76 as generating dummy fill definitions and incorporating them into the computer-readable definitions of functional layer parts. By way of example, box 76b shows how the functional features of box 56b (FIG. 1B) may be filled with dummy or nonfunctional fill squares so that the overall layout 76b appears to have a relatively uniform fill density.

In step 77, the dummy filled layer definitions are stored in a computer readable database (e.g., a storage disk farm). The amount of storage capacity needed will depend in part on how the dummy fill is defined (flat-fill versus array fill). In step 78, the database is subjected to various, automated rules checks. These may include LVS (Layout versus Schematic checks) and DRS (Design Rules compliance checks). The size of the layout-defining file for each layer may play an important in role in how quickly these checks can be performed, if at all. Sometimes a layout-defining file may be too big to be processed by a given computer system (i.e., due to system RAM limitations).

In test step 78a, a decision is made as to whether the current design passed all the checks or failed. If it failed, control is returned to step 75 or lower so that the appropriate design groups can try to make corrections. One of those corrections may include redefining how the dummy fill is generated in step 76. It may be appreciated that the dummy fill process 76 and the database storage process 77 may have to be rerun numerous times before a passing design is attained.

When the layout designs (75) for all the masks are finished, including successful dummy fill (76) and rules checking (78), the composed mask set is ready for a step known as “tape out” 79. The tape out process 79 may include transmission (79a) over a network (e.g., the internet) of database files to a mask-making facility. At the mask-making facility, the received data is first processed by error detecting and correcting software (ECC software) and after data integrity is confirmed, the database definitions are typically “flattened” (79b, arrays are reconverted to individual object definitions) and the corresponding photomasks 82 are manufactured and checked for conformance relative to the database specifications. Those skilled in the art will appreciate that database file size can affect how easily and correctly the layout data is transmitted (79a) to the mask houses, how easily or quickly it is verified by ECC methods and how easily resulting masks can be displayed on a computer screen or otherwise when conformance checking occurs.

The fully-designed wafer is now ready to enter the physical fabrication phase 80. After each of the 2D mask layout designs is digitally encoded as a respective computer data file and sent to a respective one of, or possibly more of, different mask-making houses for manufacturing of the masks, the masks are returned to the user for follow-up photolithography and other steps. Fabrication phase 80 includes a lithographic exposure state. In this state, a given wafer 85 (an in-process wafer) has been coated with a photosensitive layer (PSL) 86 and the upper surface 86a of the PSL has been planarized. Radiation 81 from a given light source or other kind of radiative source is passed through one of the manufactured photomasks 82 for projection onto PSL surface 86a. The mask image is typically transformed optically by a stepper optical system 83. By way of example, the projection transformation can include a 2D dimensional reduction of about 2 to 1 and more typically it will include a reduction amount of about 4:1 or about 5:1. The so-transformed mask image is projected into a first reticle area 84 within the larger surface area 86a of the photosensitive layer. Sufficient exposure time is provided for photochemically altering the exposed first reticle area 84. Then the stepper steps the projected mask image to a next reticle area adjacent to first area 84. The expose and step procedure is repeated until all desired reticle areas on surface 86a have been exposed. This is how the photomask 82, in essence, becomes a stamp which repeatedly imprints the reticle pattern across the wafer 85, one step after the next. Needless to say, if there is an error or defect in the way that dummy fill patterns were included into the photomask 82, that problem will be replicated many times across the entire wafer. It is important for the photomask 82 to be properly filled with dummy features when such are needed for consistent mass production results.

FIG. 1C shows that the exposed wafer 85 typically has a number of pre-patterned and/or other layers below the planarized, photosensitive layer 86. One of the subsurface layers may be a bulk substrate or other pre-patterned layer 89 which has various topographical features disposed on it such as the illustrated flat section 89a and mesa 89b. Between the pre-patterned layer 89 and the PSL 86, there will be at least one material layer 87. This at least one material layer 87 is to be next physically-patterned after the exposed photosensitive layer 86 is developed. The top surface 87a of the material layer 87 is typically planarized by CMP or other means. When done correctly, dummy fill can help to improve polishing results (e.g., reducing CMP dishing or erosion). Additionally or alternatively, optical reflections from the lower layer 89 may cause the photosensitive layer 86 to react differently due to the underlying topographical features 89a, 89b. (Often an Anti-Reflection Coating or ARC is interposed between PSL 86 and underlying layers. The ARC may not be 100% effective.) When done correctly, dummy fill can help to reduce reflection problems.

In step 90 of fabrication phase 80, the step-wise exposed photosensitive layer (PSL) 86 is developed and used to physically pattern the underlying layer material 87. The physical patterning may include plasma etching and/or other forms of physical patterning. In a subsequent step 92 it is determined whether step 90 was the last photolithographic patterning round for the in-process wafer. If the answer is NO, then a next mask is obtained in step 95 and the process is repeated by projecting further radiation through the next mask (95) and its associated optics. The associated exposure radiation (81) and/or optics (83) and/or PSL (86) of the next mask (95) can be substantially different from those used for the earlier mask 82 and as such the associated rules for dummy fill can be different. Steps 90 and 92 may be repeated many times before the answer at step 92 is YES. In each repetition, the respective material layer (87) can be substantially different as can be the respective development and patterning processes (91) as well as the resulting patterns. The completed wafer 50″ which emerges from the YES path of step 92 may subsequently be sent to a wafer sort, dice, and re-test facility.

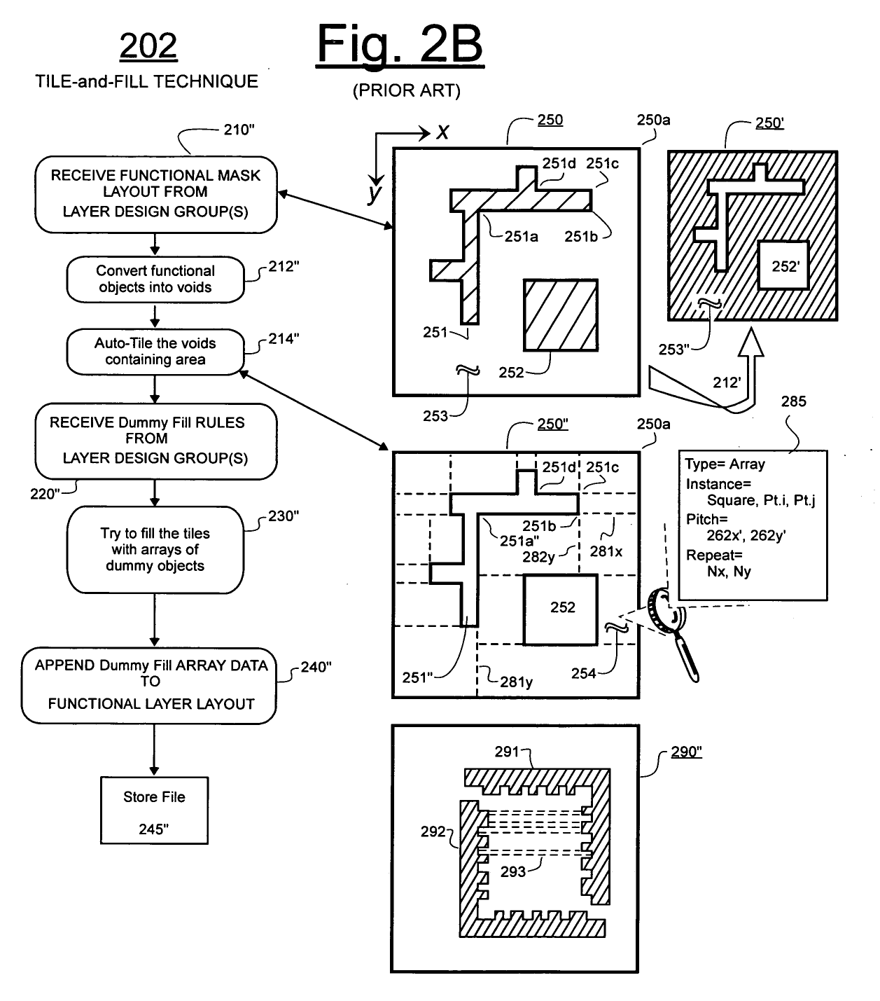

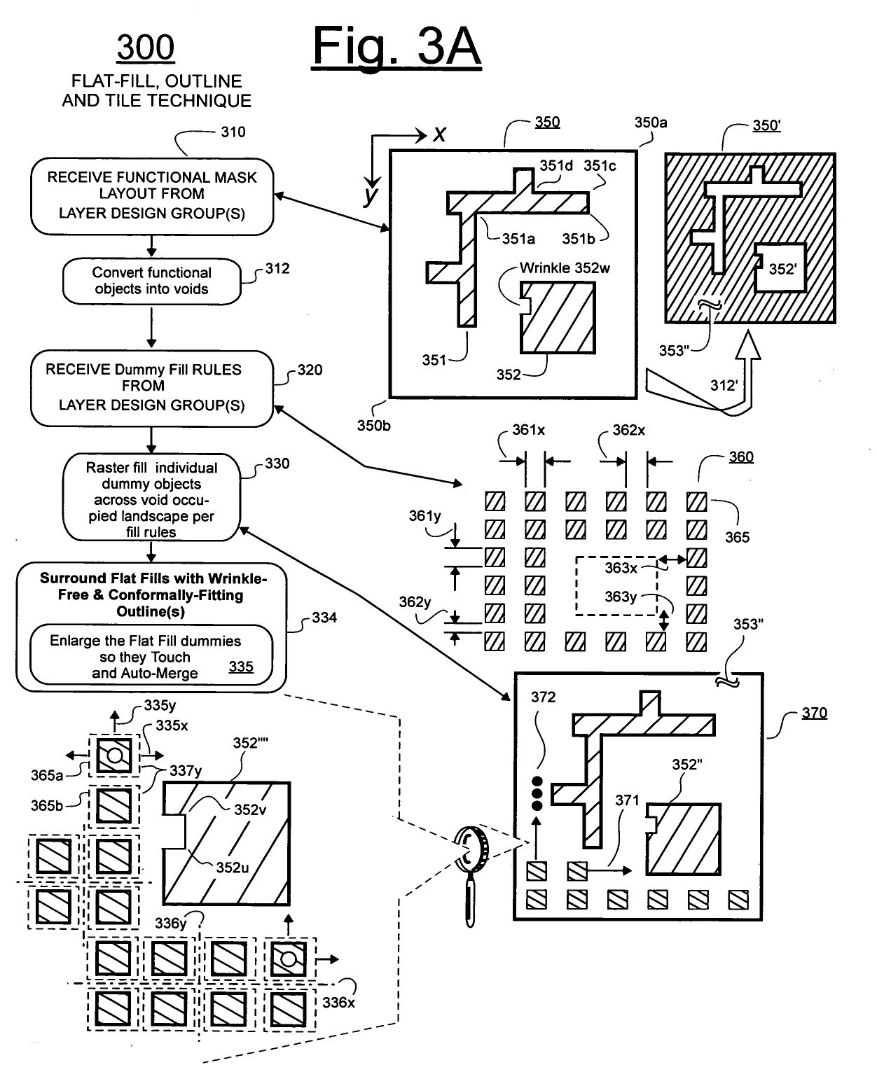

Referring to FIG. 2A, details of a conventional flat-fill process 200 are explored. At step 210, a computer-readable file is received from one of the layer design groups for defining a functional mask layout. The file may use a compilation of polygon object definitions for defining the laying out of uniquely shaped mesas or trenches in the corresponding layer of the given die or reticle. An example is shown for purpose of concrete explanation and in top plan view form at 250. It is assumed that objects 251 and 252 represent raised metal interconnect lines (mesas) on the planar surface of an underlying dielectric layer (dielectric not shown). Region 253 is empty area that is to be filled with dummy-fill objects.

In terms of more specifics, the polygon definitions provided in the received layout specification 250 will generally be described relative to a predefined coordinate system (e.g., orthogonal x and y axes as shown). The entire die or reticle area may be defined as a bounding rectangle having diagonal corner points 250a and 250b, where each of the corner points is specified as two coordinate numbers (xj, yj) on the x versus y coordinate plane. Specific objects within the bounded layout area 250 may be defined as bounded polygons having two or more vertices (i.e., corner points, cusps, angle vertex points) each. By way of example, object 251 includes vertex points such as 251a, 251b, 251c, and 251d. In commercial practice, the layout will be far more complicated than what is shown at 250. The simplified illustration 250 is provided merely for easy understanding. An actual layout may have hundreds or thousands of functional objects and each of these may be represented by large numbers of respective vertex coordinates (i.e., 251a-251d, etc. for object 251).

In a subsequent process step 212, the received computer file that describes the layer layout 250 is inverted so as to thereby convert the functional objects (i.e., polygons 251 and 252) into voids or holes while the empty space 253 is redefined as solid landscape area that is to be filled with dummy-fill objects. An example of the inverted data is shown at 250′ where region 252′ represents a square hole through the otherwise mostly solid landscape area 253′ that is to be filled with dummy objects. Symbol 212′ represents the inversion process of step 212.

At next step 220, computer-readable rules for the dummy-fill process are received from the layer design group. Specific shapes of the dummy fill objects and their dimensions as well as pitch can vary from application to application. For example, the dummy-fill objects may be specified as regularly packed hexagons, circles or stars rather than the illustrated squares. The illustration at 260 is merely an example. The received dummy-fill rules will typically specify x and y dimensions for a sample dummy-fill object such as ones illustrated at 261x and 261y. The rules will further specify a first set of spacings 262x and 262y to be maintained between adjacent dummy-fill objects. The rules will further specify additional spacings 263x and 263y to be maintained between dummy fill objects and adjacent functional objects (i.e., object 252 of layout 250). It is often the case that spacing 263x is greater than 262x and spacing 263y is greater than 262y.

Given the computerized and inverted layout file 250′ and the dummy-fill rules 260, the process next proceeds to step 230 where a raster fill is initiated in the empty space 253″ for thereby filling the open areas with dummy-fill objects 265. A sample dummy-fill object specification is shown at 275. This computer-readable specification 275 includes a first data item indicating the shape or type of the dummy-object, in this case a square. The specification 275 further includes second and third data item indicating the respective coordinates for diagonal points Pt.1 and Pt.2. In this case, therefore, each individual dummy object specification 275 contains three data items for specifying the shape, orientation and location of the corresponding dummy-object, namely the type data and the corner coordinates data. In alternate embodiments, more complex dummy objects may be specified by specifications that have larger numbers of data items for specifying their respective shapes, locations and orientations. In one embodiment of process step 230, the raster fill of the individual dummy objects begins at the left bottom corner of the fill area 270 and proceeds left to right in accordance with the specified horizontal separation dimension 262x for the dummy-objects. Any temporarily-laid down dummy-object which violates the separation rules (i.e., 263x, 263y) required between dummy and functional objects is removed either during the raster fill or shortly thereafter. Following completion of each horizontal raster fill 271, the process steps up by vertical separation distance 262y and begins a fresh horizontal raster fill operation 271. This vertical stepping up along the layout area is represented by symbol 272. The process continues until the bounded fill area 253″ has been exhausted. A possible result is shown at 276b.

At next step 240 of the flat-fill process 200, the accumulated dummy-object specifications (275) that have been generated for specifying each of the individual dummy objects are appended to the functional layer layout data received at 210 to thereby generate the dummy-filled layout file (represented as 276b).

At step 245, the dummy-filled computer file (276b) is stored in an appropriate data storage medium (e.g., magnetic or optical disk farm) for later use. Referring briefly to FIG. 1C, such later use may include any one or more of the rules checking operations 78, the tapeout step 79, the transmission of the file 79a to a prespecified mask maker via a network (i.e., the internet) and the flattening out 79b of the received file at the mask house.

Since the set of individually-specified dummy-objects can be constituted by specifications for thousands or usually millions of individual flat-fill objects and since each object consumes plural data storage regions for its respective type specification and/or vertex coordinates, the flat fill approach can consume enormous amounts of data storage area in step 245. The large size of the post-flat-fill file (276b) makes it cumbersome for handling during rules checking (78) or even simply for opening the file to display its contents on a computer screen. Additionally, it becomes a problem to transmit (79a) the large computer file over a network to the mask house because large files are more prone to being damaged by in-transit error (noise). If a file is extremely large, it may be very time consuming and troublesome to transmit an error free version of it to the intended destination.

Given this, there has been a long felt desire in the industry to find a way of reducing the amount of storage data needed for generating dummy-fill specifications. One alternate and previously tried method is known as the tile-and-fill technique. Referring to FIG. 2B, a flow chart for the tile-and-fill technique is shown at 202. Where practical, like reference numbers, but with double prime suffixes (e.g., 210″) are used for steps in FIG. 2B that have similar counterparts in FIG. 2A and thus detailed explanations will not be repeated. At step 210″ the functional mask layout is received from the layer design group. At step 212″ the functional objects are converted into voids. Beginning at step 214″ the process diverges from that of FIG. 2A in that, at this stage, the voids-containing landscape area 253″ is auto-tiled. A generic tiling program is used to auto-tile the voids-containing area 253″. Quite often the tiling program will initially focus its efforts on the vertex coordinates of the voids (e.g. 251″) and extend tile boundaries from such vertex points. Accordingly, corner point 251a″ will result in the production of horizontal tiling boundary 281x and vertical tiling boundary 281y. The vertex points of the other voids will generate similar initial tiling boundaries. Thereafter, the tiling program will attempt to finish filling the voids-containing area 253″ with additional boundary lines until the area 253x is tessellated (fully tiled) with rectangles. By way of example, one tessellating rectangle may appear to the right of void 252″ as is illustrated at 254.

At next step 220″, the automated process receives dummy-fill rules from the design group. At subsequent step 230″ the automated process “tries” to fill the generated tiles of step 214″ with arrays of dummy objects in accordance with the received dummy-fill rules (220″). More specifically, referring to tile rectangle 254, the corresponding array that fills this rectangle 254 may be specified in accordance with the data structure shown at 285. Data structure 285 specifies itself as being of type, array. Data structure 285 further specifies an instance of the array as being a square having diagonal corner points Pt.i and Pt.j and respective separation pitches corresponding to 262x and 262y. Further the array data structure 285 will include repeat value specifications indicating the number of instances across each row (Nx) and the number of columns per row (Ny). Although an individual array structure 285 typically contains many more data items than an individual flat fill object 275 (FIG. 2A), after a certain threshold number of individual flat fill objects is surpassed, the size of the array data structure 285 will be significantly smaller than that of flat fill data specifying a same number of objects individually in flat-fill format.

In step 240″ the generated and accumulated array data (285) is appended to the file data for the functional layer layout and in step 245″ the compiled data is stored.

While this tile-and-fill technique 202 appears to solve the problem of generating fill data while consuming less storage space, in actual practice its performance is sometimes far worst than that of the older flat-fill technique 200. Unaccounted-for “wrinkles” can confound the process. Note that step 230″ is characterized as “trying” to fill the generated tiles with the arrays of dummy objects. Not every try is successful. In some cases large numbers of tiles remain unfilled because the tile dimensions are too narrow to allow any dummy objects to be filled into such tiles. Large empty spaces may be left behind simply because the auto-tile program generated narrow elongated rectangles in places where it might have generated wider rectangles.

Exemplary layout 290″ shows how this can happen. Functional objects 291 and 292 have arbitrarily placed vertex points that locate relative to one another so as to encourage generation of narrow tiling boundaries. For example, interaction between slots and ribs in the randomly situated objects 291-292 can fool the automated tiling program into generating very closely-spaced initial tiling boundaries such as the pair shown at 293. These closely-spaced boundaries will produce narrow tiling rectangles which cannot be filled with dummy-fill objects. As a result, the entire large area between exemplary objects 291 and 292 may go unfilled. The interior slots and ribs of exemplary, functional features 291 and 292 may be deemed as part of a larger set of closely-spaced “wrinkles” that can plague the shape of a functional object in actual commercial practice. Such wrinkles need not be defined by rectangular slots or ribs. Any set of closely spaced vertices (where close spacing is relative to the dimensions of the dummy-fill rules), including minor kinks and bends in the border of each functional feature can fool the auto-tiling software into generating tiling boundaries that are too small to later accommodate the dummy-fill objects.

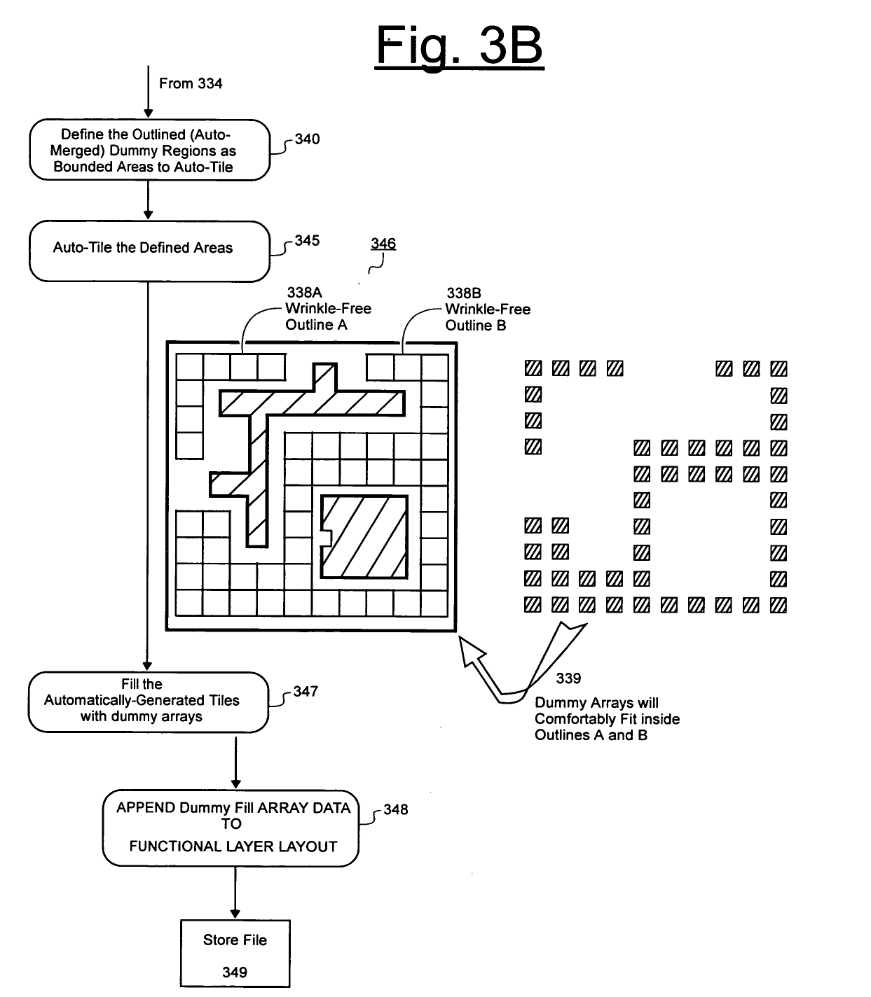

Referring to FIGS. 3A-3B, a solution to the above detailed problems will now be described. Where practical, like reference numbers in the “300” century series are used for elements of FIG. 3A which correspond to but are not all necessarily the same as the elements represented by similar symbols and reference numbers of the “200” century series in FIG. 2A. As such, detailed explanations will not be repeated for steps already covered. A small “wrinkle” 352w (e.g., a small cutout) has been added to square feature 352 for explaining below one aspect of the invention. At step 310 the functional mask layout is received from the layer design group. At step 312 the functional features are converted into voids (i.e., wrinkled square hole 352′). At step 320 the fill rules are obtained. In one set of embodiments, the respective, functional-to-dummy object spacings 363x, 363y are always substantially greater than the respective, dummy-to-dummy object spacings 362x, 362y. At step 330, the solid landscape area 353″ is flat filled with individually-specified dummy-object (e.g., 275 of FIG. 2A) in accordance with the specified fill rules. Beginning at step 334 the process 300 diverges from that of FIG. 2A in that at this stage a conformal and substantially wrinkle-free outline is automatically generated for each group of contiguous and fill-rule-wise spaced dummy-objects. A variety of techniques may be used for automatically generating the conformal and substantially wrinkle-free outlines. By way of example, a space filling algorithm locates empty spaces having x or y bounds corresponding to the dummy-to-dummy object spacings 362x, 362y and repaints those identified dummy-to-dummy object spacings as solid by joining the dummy-objects on opposite sides of each dummy-to-dummy object spacings 362x or 362y.

In one embodiment, however, it has been found that the outlines may be generated in a very quick and simple way 335. Assuming all the dummy-objects (i.e., 365) are equally spaced apart squares, a command is issued to automatically enlarge all such objects symmetrically (from their respective geometric centers) by an amount (335x, 335y) that causes them to just touch each other. The computer program that performs this automated object-size expansion includes an auto-merge feature. It recognizes that when two polygons just touch or overlap one another, that those polygons should be merged into a singly defined polygon. Accordingly, as the dummy-objects are automatically enlarged (335x, 335y) so as to meet with one another at their mutual centerlines of spacing (e.g., 336y), they also auto-merge to thereby define one or more, conformably fitting outlines (e.g., including loosely fitting outlines like custom tailored and wrinkle-free clothing) of the areas that were filled by the flat dummy fill operation of step 330.

An important aspect to pay attention to is that vertices of each generated outline are blind to small wrinkles in adjoining functional features (i.e., 352″). More specifically, vertices 352v and 352u of adjoining functional object 352″″ do not affect how the vertical outline front 337y develops. The outline front 337y develops from the sides and dimensions of the pre-fitted flat-fill objects (365a, 365b) and it (337y) is thus not dependent on the potentially arbitrary placement of wrinkle-defining vertices such as 352v and 352u in an adjoining functional object. The resulting outlines (see 338A and 338B of FIG. 3B) will therefore not have arbitrary vertices included in them as a result of minute kinks, cutouts, projections or other wrinkles (i.e., cutout 352v-352u) found on the adjoining functional objects (i.e., 352″″). As a result, the auto-tile step (350 of FIG. 3B) will not home in on such vertices of minute wrinkles and it will not start auto-tiling relative to them. Instead it will use the vertices of the substantially wrinkle-free outlines (e.g., 338A and 338B) to form rectangles into which dummy arrays can be comfortably and efficiently be fitted.

Returning to step 334 for a bit longer, it is to be observed that symmetrical enlargement of all dummy-objects is not the only way to generate such conformably-fitting (and optionally, loosely fitting) and substantially wrinkle-free outlines surrounding the pre-situated flat fills (365a, 365b, etc.). After reading the present disclosure, those skilled in the art will see a number of alternate ways in which the basic concept described herein can be carried out for thereby automatically generating wrinkle-free outlines between wrinkle-infected, functional objects. The various modifications are to be considered as being within the scope of disclosure here. Without wishing to be bound to only these possible variations, the variations may include the following and alternate ways of generating wrinkle-free outlines: (A) extend the position of each side of a first dummy object toward a counterfacing side of a second dummy object only if that counterfacing side is spaced away by less than or the same amount of distance as the fill-rule specified distance for inter-dummy spacing; and after all such inter-dummy spacings are re-colored as solid areas, optionally further extend the sides of the resulting outline (i.e., in the x or y direction) by a prespecified second distance so as to allow for comfortable placement of dummy arrays (where the members of the array do not touch the border of the outline and are thus adequately spaced apart for functional objects that lie outside the border of the outline); or (B) after flat-filling, locate linear arrays of adjacent dummy objects by testing their corner points for curve fitted match to regular placement along a linear position function (e.g., along a hypothetical horizontal or vertical line with some small amount of predefined error allowed) and then convert the found set of adjacent dummy objects into an encompassing polygon that will be part of the generated outline.

Referring next to FIG. 3B, in step 340, after the conformal outlines have been defined in step 334, the conformal outlines are redefined as empty areas that are to be tiled with rectangles by a generic auto-tile program. In step 345 the automated tiling is carried out. An example of the outlines is shown at 346, just below step 345. The generated tiles are not specifically shown. However the generated tiles can be any suitable set of rectangles formed of immediately adjacent squares in wrinkle-free Outline-A (338A) or wrinkle-free Outline-B (338B). Symbol 339 indicates that the flat-fill pattern earlier formed in step 330 will comfortably fit inside the generated tiles because each square in Outline-A (338A) or Outline-B (338B) has room for accommodating a corresponding dummy-object.

At step 347, the generated tiles are each filled with a corresponding array of dummy-objects, where the array of dummy-objects is specified with compact code in accordance with data structure 285 for example. Since one or more array specifications (i.e., 285) are used instead of individually-specified dummy-objects (i.e., 275), the dummy-fill data can be substantially more compact than that of a comparable flat-fill (i.e., 217, 272). However, since a flat-fill approach is used to layout (or at least estimate) the locations of the array specifications, the arrays will fill up empty space in the functional layout (e.g., 350) with substantially the same space-filling efficiency as does a conventional flat-fill technique (200).

At step 348, the automatically generated array definitions are appended to the functional layout definition. The resulting filed data is stored in step 349.

The array-containing file(s) that are stored by step 349 may thereafter be used in the associated steps of FIG. 1C, such as for carrying out rules checking (78), performing a tapeout (79), transmitting the tapeout over a network (79a) and testing the received transmission with use of error-check and correction software (ECC) at the mask house before flattening the received data.

The present disclosure is to be taken as illustrative rather than as limiting the scope, nature, or spirit of the subject matter claimed below. Numerous modifications and variations will become apparent to those skilled in the art after studying the disclosure, including use of equivalent functional and/or structural substitutes for elements described herein, use of equivalent functional couplings for couplings described herein, and/or use of equivalent functional steps for steps described herein. Such insubstantial variations are to be considered within the scope of what is contemplated here. Moreover, if plural examples are given for specific means, or steps, and extrapolation between and/or beyond such given examples is obvious in view of the present disclosure, then the disclosure is to be deemed as effectively disclosing and thus covering at least such extrapolations.

By way of example of such modifications, variations and/or extrapolations, it is understood that the configuring of a computer or other instructable machine to carry out automated dummy-fill operations in accordance with the disclosure is also within the contemplation of the present disclosure. A computer-readable medium or another form of conveyance for a software product or machine-instructing means (including but not limited to, a hard disk, a compact disk, a flash memory stick, or a downloading of manufactured instructing signals over a network) may be used for instructing an instructable machine to carry out one or more of the novel steps described herein, including the step of generating the substantially wrinkle-free outlines. The internet or another form of network may be used for transmitting database files whose included array definitions were formed from the substantially wrinkle-free outlines.

### Reservation of Extra-Patent Rights, Resolution of Conflicts, and Interpretation of Terms

After this disclosure is lawfully published, the owner of the present patent application has no objection to the reproduction by others of textual and graphic materials contained herein provided such reproduction is for the limited purpose of understanding the present disclosure of invention and of thereby promoting the useful arts and sciences. The owner does not however disclaim any other rights that may be lawfully associated with the disclosed materials, including but not limited to, copyrights in any computer program listings or art works or other works provided herein, and to trademark or trade dress rights that may be associated with coined terms or art works provided herein and to other otherwise-protectable subject matter included herein or otherwise derivable herefrom.

If any disclosures are incorporated herein by reference and such incorporated disclosures conflict in part or whole with the present disclosure, then to the extent of conflict, and/or broader disclosure, and/or broader definition of terms, the present disclosure controls. If such incorporated disclosures conflict in part or whole with one another, then to the extent of conflict, the later-dated disclosure controls.

Unless expressly stated otherwise herein, ordinary terms have their corresponding ordinary meanings within the respective contexts of their presentations, and ordinary terms of art have their corresponding regular meanings within the relevant technical arts and within the respective contexts of their presentations herein.

Given the above disclosure of general concepts and specific embodiments, the scope of protection sought is to be defined by the claims appended hereto. The issued claims are not to be taken as limiting Applicant's right to claim disclosed, but not yet literally claimed subject matter by way of one or more further applications including those filed pursuant to 35 U.S.C. §120 and/or 35 U.S.C. §251.

What is claimed is:

1. An automated method for generating dummy fill specifications for filling empty space between functional features of a specified functional layout with dummy-objects, the method comprising:
(a) automatically flat-filling the empty space with dummy-objects;
(b) automatically forming conformal outlines of contiguous sections of the flat-filled dummy-objects; and
(c) automatically tiling areas bounded by the conformal outlines to thereby define tiles within one or more of the conformal outlines.

2. The method of claim 1 wherein one or more of said functional features of the specified functional layout includes wrinkles and wherein:
(b.1) the conformal outlines are substantially free of vertices aligned with said wrinkles of the functional features.

3. The method of claim 1 wherein:
(b.1) said step of forming conformal outlines includes automatically enlarging dimensions of dummy-objects in said flat-filled empty space.

4. The method of claim 1 wherein:
(a.1) each of said flat-filling dummy object is defined by a computer-readable and corresponding data structure having a first data item indicating the shape or type of the corresponding dummy-object, a second data item defining a location of a first critical point in the identified type or shape of dummy-object, and a third data item defining a further critical feature of the identified type or shape of dummy-object so that the data structure thereby individually specifies the shape, orientation and location of the corresponding dummy-object.

5. The method of claim 1 wherein:
(a.1) each of said flat-filling dummy object is a rectangle defined by a computer-readable and corresponding data structure having first and second data items respectively defining locations of opposed corners of the corresponding rectangle.

6. The method of claim 1 and further comprising:
(d) automatically defining arrays of dummy object polygons for filling one or more of the tiles.

7. The method of claim 6 wherein each automatically defined array is a computer-readable data structure having:
(d.1) first data that identifies the data structure as being of an array type;
(d.2) second data that specifies an instance of a dummy object the array in terms of size, shape and/or orientation;
(d.3) third data that specifies one or more separation pitches for plural dummy objects in the array; and
(d.4) fourth data that specifies the number of plural dummy objects that are within the array.

8. The method of claim 6 wherein said fourth data specifies the number of dummy objects to appear in each row of the array and the number of dummy objects to appear in each column of the array.

9. The method of claim 6 and further comprising:
(e) automatically appending the defined arrays of dummy object polygons to a file containing definitions of functional objects.

10. The method of claim 9 and further comprising:
(f) opening the appended file.

11. The method of claim 10 and further comprising:
(g) performing a predefined and automated rules checking operation on the opened file.

12. The method of claim 9 and further comprising:
(f) transmitting the appended file.

13. The method of claim 12 and further comprising:
(g) performing an automated error checking operation on a transmitted version of the appended file.

14. The method of claim 12 and further comprising:
(g) manufacturing a lithography mask in accordance with object definitions provided by the appended file.

15. The method of claim 12 and further comprising:
(g) manufacturing a plurality of integrated circuits in accordance with object definitions provided by the appended file.

16. A monolithic integrated circuit comprising:
a plurality of functional layers each having a respective plurality of functional features and wherein:
(a) at least a given one of the functional layers further includes a plurality of dummy features interspersed between the functional features of the given functional layer, and
(b) said dummy features are interspersed in accordance with one or more data arrays where the data arrays are produced by a method comprising:
(b.1) receiving a computer readable specification of a layout of functional features occupying the given layer;
(b.2) receiving a computer readable specification defining rules for filling empty space between the functional features of the given layer with dummy-objects;
(b.3) automatically flat-filling the empty space with dummy-objects;
(b.4) automatically forming conformal outlines of contiguous sections of the flat-filled dummy-objects; and
(b.5) automatically tiling areas bounded by the conformal outlines to thereby define tiles within one or more of the conformal outlines.

17. A manufactured data file which defines a layout of functional features and dummy-fill objects for a given one or more layers of a to-be-manufactured, monolithic integrated circuit where said data file is the product of a process comprising:
(a) receiving a computer readable specification of a layout of functional features occupying the given layer;
(b) receiving a computer readable specification defining rules for filling empty space between the functional features of the given layer with dummy-objects;
(c) automatically flat-filling the empty space with dummy-objects;
(d) automatically forming conformal outlines of contiguous sections of the flat-filled dummy-objects; and
(e) automatically tiling areas bounded by the conformal outlines to thereby define tiles within one or more of the conformal outlines.
